(19) United States
(12) Patent Application Publication
(10) Pub. No.: US 2025/0098541 A1
(43) Pub. Date: Mar. 20, 2025

(54) ACOUSTIC RESONANCE SENSOR DEVICES FOR RADICAL SPECIES DETECTION WITH ENHANCED FILTERS

(71) Applicant: Applied Materials, Inc., Santa Clara, CA (US)

(72) Inventors: Jia Pelpa, Sunnyvale, CA (US); Mehran Moalem, Fremont, CA (US); Mehdi Balooch, Berkeley, CA (US); Damodar Shanbhag, Chandler, AZ (US)

(21) Appl. No.: 18/883,312

(22) Filed: Sep. 12, 2024

Related U.S. Application Data
(60) Provisional application No. 63/539,183, filed on Sep. 19, 2023.

(51) Int. Cl. H10N 30/30; G10K 11/04; H10N 30/03; H10N 30/067; H10N 30/082; H10N 30/85; H10N 30/87

(52) U.S. Cl. CPC H10N 30/302; G10K 11/04; H10N 30/03; H10N 30/067; H10N 30/082; H10N 30/852; H10N 30/871

(57) ABSTRACT

A device can include a radical sensor including a piezoelectric resonator. The radical sensor includes a base structure including a piezoelectric material, and a filter formed on the base structure to selectively react with a radical species. A resonant frequency of the radical sensor changes in response to reaction of the radical species to the filter. The filter includes at least one of: a crystalline material, a doped coating, or a coating having a thickness that ranges from about 5 micrometers to about 50 micrometers.

### CROSS-REFERENCE TO RELATED APPLICATION(S)

The present application claims priority to U.S. Provisional Patent Application No. 63/539,183, filed on Sep. 19, 2023 and entitled “ACOUSTIC RESONANCE SENSOR DEVICES FOR RADICAL SPECIES DETECTION WITH ENHANCED FILTERS”, the entire contents of which are hereby incorporated by reference herein.

### TECHNICAL FIELD

The instant specification relates to components and apparatuses for semiconductor manufacturing. More specifically, the instant specification relates to acoustic resonance sensor devices for radical species detection with enhanced filters.

### BACKGROUND

Electronic devices, such as integrated circuits, are made possible by processes which produce intricately patterned material layers on substrate surfaces. Forming patterned material layers on a substrate can be performed using controlled methods for forming and removing material. Such methods can use gases to deposit layers, etch layers, clean substrates, and so on. Some processes are plasma-enhanced, during which a plasma can be formed and used during deposition, etching, cleaning, etc. A gas flow sensor, such as a mass flow controller, can be used to detect the amount of gas that is flowed. However, some gas flow sensors can measure a total amount of gases, and cannot measure specific subspecies of a gas, such as the amount of radical species and/or ions in a gas. For example, a mass flow controller can measure a total gas flow, but cannot measure an amount of any specific type of gas or an amount of a specific molecular species of a particular type of gas. Also, some sensors are made from machinable materials that can corrode in the presence of radical species, such as stainless steel.

In electronic device processing, radical species are often used for various processing operations in a processing chamber (“chamber”). For example, a radical species, such as atomic fluorine, may be used in an etch process or a chamber cleaning process. Radical species can be formed by various processes. One process to generate radical species is to use a plasma. For example, a gas or gas mixture including fluorine (F₂) can be flown into the chamber, and the plasma can break the compound into elemental fluorine (F). Radical species are highly chemically reactive.

Process control of radical species is difficult. Particularly, it may not be possible to effectively measure radical species concentration in a chamber. This is due, in part, to the highly reactive nature of the radical species. A radical species can react whenever the radical species contacts any surface or other compound. Even if the surface does not react with the radical species, it still may serve as a site for recombination of the radical species with each other thus converting the species to other useless compounds. As such, some mass spectrometry tools may not be able to measure the concentration of radical species. Without the ability to quantitatively measure radical species concentrations, effective process control, such as closed loop control, is not possible in existing electronic device manufacturing tools. Closed loop control refers to the use of measurements as a feedback signal to a controller in order to modify processing conditions in an ongoing process.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In some embodiments, a device is provided. The device includes a radical sensor including a piezoelectric resonator. The radical sensor includes a base structure including a piezoelectric material, and a filter formed on the base structure to selectively react with a radical species. A resonant frequency of the radical sensor changes in response to reaction of the radical species to the filter. The filter includes at least one of: a crystalline material, a doped coating, or a coating having a thickness that ranges from about 5 micrometers to about 50 micrometers.

In some embodiments, a method is provided. The method includes obtaining a base structure of a radical sensor including a piezoelectric resonator, the base structure including a piezoelectric material, and forming, on the base structure, and a filter including a crystalline material to selectively react with a radical species. A resonant frequency of the radical sensor changes in response to reaction of the radical species to the filter.

In some embodiments, a method is provided. The method includes obtaining a base structure of a radical sensor including a piezoelectric resonator, the base structure including a piezoelectric material, and forming, on the base structure, a filter including a coating to selectively react with a radical species. A resonant frequency of the radical sensor changes in response to reaction of the radical species to the filter. Forming the filter includes at least one of: doping an initial coating with a dopant to form the coating, using a base material and the dopant to deposit the coating, forming the coating to have a thickness that ranges from about 5 micrometers to about 50 micrometers, or forming the coating using a deposition process performed at a temperature ranging from about 150° C. to about 450° C.

### BRIEF DESCRIPTION OF THE DRAWINGS

The present disclosure is illustrated by way of example, and not by way of limitation in the figures of the accompanying drawings.

FIG. 1 is a sectional side view of an example manufacturing system including an acoustic resonance sensor device for radical species detection, according to some embodiments.

FIGS. 2A-2B are views of an example acoustic resonance sensor device for radical species detection, according to some embodiments.

FIGS. 3A-3D are views of an example radical sensor of an acoustic resonance sensor device for radical species detection, according to some embodiments.

FIGS. 4A-4B are cross-sectional views of the formation of an example radical sensor of an acoustic resonance sensor device for radical species detection, according to some embodiments.

FIG. 5 is a cross-sectional view of an example radical sensor of an acoustic resonance sensor device for radical species detection, according to some embodiments.

FIG. 6 shows an example equivalent circuit for a radical sensor of an acoustic resonance sensor device for radical species detection, according to some embodiments.

FIGS. 7-8B are flowcharts of example methods for manufacturing an acoustic resonance sensor device for radical species detection, according to some embodiments.

FIG. 9 is a flowchart of an example method for utilizing an acoustic resonance sensor device for radical species detection, according to some embodiments.

### DETAILED DESCRIPTION

Embodiments of the present disclosure relate to acoustic resonance sensor devices for radical species detection with enhanced filters. Plasma enhanced deposition processes may energize one or more constituent precursors to facilitate the formation of layers of materials (e.g., films) on a substrate. Any layers may be produced to develop semiconductor structures, display structures, and/or other types of structures, including conductive and dielectric films, as well as films to facilitate transfer and removal of materials. For example, hardmask films may be formed to facilitate patterning of a substrate, while protecting the underlying materials to be otherwise maintained. In many processing chambers (“chambers”), a number of precursors may be mixed in a gas panel and delivered to a processing region of a chamber where a substrate may be disposed.

As device features reduce in size, tolerances across a substrate surface may be reduced, and material property differences across a film may affect device realization and uniformity. Many chambers include a characteristic process signature, which may produce non-uniformity across a substrate. For example, the formation of radical species within the processing region and/or presence of remotely generated radical species present within the processing region may affect deposition times and profiles.

Some gas sensors (e.g., such as those in mass flow controllers) measure a total amount of gases, and cannot distinguish between specific species of molecules and/or atoms of gases. For example, a mass flow controller can measure a total gas flow, but cannot measure an amount of any specific type of gas or an amount of a specific molecular species of a particular type of gas.

In some embodiments, a chamber incorporates an acoustic resonance sensor device for radical species detection. An acoustic resonance sensor device can include a radical sensor to detect and/or measure radical species (e.g., plasma radical species) within a processing region of the chamber. For example, the processing region can be a region proximate to a substrate support of the chamber. A radical sensor device described herein may be designed to measure an amount of a radical species, such as fluorine radicals, hydrogen radicals, nitrogen radicals, etc., which other sensor devices may be incapable of detecting without use of expensive optical equipment such as spectroscopy equipment.

A radical sensor described herein can be used to measure amounts and/or concentrations of a radical species of a target gaseous species. In some embodiments, the radical sensor includes a piezoelectric resonator. The piezoelectric resonator can include a base structure including piezoelectric material that oscillates at a measurable resonant frequency. In some embodiments, the piezoelectric material includes a crystal.

In some embodiments, the base structure further includes at least one electrode formed on the piezoelectric material. For example, the at least one electrode can include a front electrode formed on a frontside of the piezoelectric material and/or a back electrode formed on a backside of the piezoelectric material. The frontside can correspond to a flat face of the piezoelectric material, and the backside can correspond to a convex face of the piezoelectric material. The at least one electrode can be formed from any suitable metal. Examples of suitable metals include aluminum (Al), gold (Au), etc.

The piezoelectric resonator can further include a filter (e.g., chemical filter) formed on the piezoelectric material. In some embodiments, the filter is formed on an electrode (e.g., the front electrode). The filter is a specialized filter can be used to filter out all molecules except for the radical species of the target gaseous species. The filter can change mass based on the reaction of the filter to the select molecular gaseous species (e.g., to radical species of a particular molecule). The change in the filter's mass can cause the resonant frequency at which the piezoelectric material oscillates to change. This change in the resonant frequency is measurable, and may be used to determine the quantity of the molecular species that reacted with the filter. Accordingly, a radical sensor described herein can include a filter, formed on a surface of a piezoelectric material, that is reactive to a target radical species of a target gas or molecule, but that is not reactive to stable molecules of the gas or molecule or to radical or stable species of other gases or molecules that are flowed together with the target gas or molecule.

In some embodiments, the piezoelectric resonator is a quartz crystal microbalance (QCM) resonator that uses a quartz crystal including silicon dioxide (SiO₂) as a piezoelectric material. A QCM resonator can be used to detect changes in the resonance frequency of the quartz crystal, which can be used to measure an amount and/or concentration of radical species.

A piezoelectric resonator can be designed for a specific application, and the filter of the piezoelectric resonator can include a material reactive to only radicals formed from a select molecular gaseous species used in the specific application. Examples of specific applications include etch operations, plasma assisted deposition processes (e.g., plasma assisted atomic layer deposition), etc. In an example, for a fluorine-based etch process, an etch rate of the chemical filter film or the etch rate of the piezoelectric crystal may strongly correlate to a concentration of fluorine radicals. Without the use of a radical sensor device including a suitable piezoelectric resonator (e.g., QCM resonator), the concentration of fluorine may not be directly detectable, and so engineers would guess at the concentration of fluorine radicals based on other known values such as a known plasma power, a known gas flow rate, and so on. By using a radical sensor including a suitable piezoelectric resonator as described herein (e.g., QCM resonator), the amount of fluorine radicals being flowed may be directly measured, and this measurement may be used to finely control the amount of radicals being output by a plasma source, such as a remote plasma source (RPS).

A radical sensor described herein can obtain a measurement of the amount and/or concentration of a radical species, which can enable closed loop control of a processing environment based on the measurement. Closed loop control refers to the use of measurements as a feedback signal to a controller in order to modify processing conditions in an ongoing process. For example, a radical sensor described herein can measure the amount and/or concentration of the radical species to obtain a measured value, and the measured value can be compared to a setpoint value. When the measured value is below the setpoint value, processing parameters may be changed to increase the generation rate and output concentration of radical species. Alternatively, when the measured value is above the setpoint value, processing parameters may be changed to decrease the concentration of radical species. As such, a radical sensor described herein can be used to implement more stable and reproducible processes.

In some implementations, the filter of the piezoelectric resonator of a radical sensor is formed as coating. For example, the coating can include a film of an amorphous material (e.g., amorphous SiO₂). However, such coatings can degrade relatively quickly over time due to mass reduction caused by radical species (e.g., etching), which may prompt replacement of the piezoelectric resonator. Additionally, the degradation can affect the ability of the radical sensor to perform radical species detection.

To improve the lifespan and performance of a radical sensor device, embodiments described herein can be used to form an enhanced filter on a base structure of a piezoelectric resonator. In some embodiments, a piezoelectric resonator is a QCM resonator. The base structure can include a piezoelectric material. In some embodiments, the base structure further includes at least one electrode formed on the piezoelectric material. For example, the at least one electrode can include a front electrode and/or a back electrode, as described above. The at least one electrode (e.g., a coating of the at least one electrode) can include any suitable material in accordance with embodiments described herein. Examples of suitable materials include Al, Au, etc. The enhanced filter can have a more stable reaction and/or a lower rate of reaction with a radical species, while still being unreactive to a non-radical species (e.g., a more stable reaction and lower rate of reaction with atomic fluorine (F), while still being unreactive to molecular fluorine (F₂)).

In some embodiments, the enhanced filter is formed on the front electrode of the piezoelectric resonator. In some embodiments, the base structure does not include a front electrode, and the enhanced filter is formed directly on the piezoelectric material. Various methods for forming an enhanced filter are contemplated.

In some embodiments, forming an enhanced filter on a base structure of a piezoelectric resonator includes forming a crystalline material on the base structure. For example, the crystalline material can be formed on a front electrode of the base structure. In some embodiments, the crystalline material is a polycrystalline material. In some embodiments, the crystalline material includes SiO₂.

An interface between the crystalline material and the base structure can be a high-quality interface to enable an acoustic wave to travel through the interface. For example, a high-quality interface can be an interface having a suitable porosity. In some embodiments, a high-quality interface has a porosity of less than or equal to about 20%, a porosity of less than or equal to about 30%, or a porosity of less than or equal to 40%.

In some embodiments, the crystalline material is cut from a base material. For example, the crystalline material can include a SiO₂ crystal (e.g., polycrystalline SiO₂) cut from a base quartz material. In some embodiments, the crystalline material has a thickness that ranges from about 5 micrometers to about 50 micrometers.

In some embodiments, forming the crystalline material on the base structure includes attaching or bonding the crystalline material to base structure (e.g., the front electrode). For example, forming the crystalline material on the base structure can include using a bonding layer (e.g., glue) to attach the crystalline material to a surface of the base structure (e.g., a surface of the front electrode). The bonding layer can have suitable properties to enable an acoustic wave to penetrate through an interface. In some embodiments, the bonding layer improves an interface between the crystalline material and the base structure (e.g., reduces a porosity at the interface between the crystalline material and the base structure, such as by flowing to fill pores or voids at the interface).

In some embodiments, forming the crystalline material on the base structure includes etching the crystalline material of the piezoelectric material. More specifically, the base structure can lack a front electrode, and a mesh can be formed directly on a surface of the piezoelectric material. In some embodiments, forming the mesh includes placing the mesh on the surface of the piezoelectric material. In some embodiments, forming the mesh includes depositing the mesh on the surface of the piezoelectric material. The mesh can include any suitable material in accordance with embodiments described herein. Examples of suitable materials include Al, Au, nickel (Ni), etc. After the mesh is formed, a radical species can then be used to etch the piezoelectric material in a pattern defined by the mesh. In such an embodiment, the front surface of the piezoelectric material of the base structure itself acts as the filter, and so the base structure may be composed of a material that is selectively reactive to a target radical. In some embodiments, the base structure is or includes SiO₂.

In some embodiments, the filter includes a crystal structure having a number of grains. A grain can refer to a region within which the crystal lattice has a particular orientation. A crystal structure (e.g., polycrystalline material) can include multiple grains each having a respective orientation (e.g., random orientation) within the crystal structure. A pair of grains of a crystal structure can be separated by an interface referred to as a grain boundary. In some embodiments, a grain has a microstructure grain size selected to achieve a target filter lifetime depending on process conditions within which the radical sensor operates. In some embodiments, the microstructure grain size ranges between about 100 nanometers to about 50 micrometers, such as 200 nanometers, 300 nanometer, 400 nanometer, 500 nanometers, 1 micrometer, 5 micrometers, 10 micrometers, 25 micrometers, and so on. Additionally, increasing grain boundary size can increase the activation energy needed to induce a chemical reaction. Therefore, increasing grain boundary size can result in a greater amount or concentration of radical species being accumulated before etching of the material of the filter occurs.

In some embodiments, forming an enhanced filter on a base structure of a piezoelectric resonator includes forming an enhanced coating on the base structure. For example, the enhanced coating can be formed on a front electrode of the base structure.

In some embodiments, forming the enhanced coating on the base structure (e.g., on the front electrode) includes forming a coating on the base structure using a high temperature deposition process. In contrast to deposition processes that performs an initial low temperature or “cold” deposition of material, a high temperature deposition process maintains a high temperature throughout the entire process. An enhanced coating formed using a high temperature deposition process can exhibit decreased etch rates when exposed to a radical species as compared to a coating formed using other deposition processes. In some embodiments, the high temperature deposition process is performed at a temperature that ranges from about 150° C. to about 450° C., such as 200° C., 250° C., 300° C., 350° C., or 400° C. Examples of deposition processes that can be used to perform a high temperature deposition process include physical vapor deposition (PVD) (e.g., magnetron sputtering or electron beam evaporation), atomic layer deposition (ALD), chemical vapor deposition (CVD), plasma spray, ion assisted deposition (IAD), etc. In some embodiments, a deposition process is a thin-film deposition process.

For example, the deposition process can be electron beam evaporation. Electron beam evaporation is a type of PVD process. During electron beam evaporation, a target material (e.g., anode) is bombarded with an electron beam. The electron beam can be generated from a filament (e.g., tungsten filament) and steered by electric and magnetic fields to strike the target material. The electron beam causes atoms from the target material to transform into a gaseous phase. These atoms can then precipitate into solid form, coating surfaces with a layer of the target material. Electron beam evaporation can occur under high vacuum conditions to avoid contamination. In some embodiments, the deposition process is ion-assisted electron beam evaporation. During ion-assisted electron beam evaporation, an ion beam including ions (e.g., argon ions) with various energies can be directed to a target substrate along with the target material. The ion beam can impart energy into the gaseous phase atoms to improve properties of the layer of the target material (e.g., adhesion, density and/or grain structure).

In some embodiments, forming the enhanced coating on the base structure includes forming a thick coating on the base structure using a deposition process. In some embodiments, the deposition process is a high temperature deposition process, as described above. A thicker coating can increase the lifespan of the piezoelectric resonator. However, too thick of a coating can have a negative impact on performance of the piezoelectric resonator by blocking the transmission of acoustic waves. Thus, the thickness of the coating can be optimized to balance piezoelectric resonator lifespan with piezoelectric resonator performance. In some embodiments, the thick coating has a thickness that ranges between about 5 micrometers to about 50 micrometers, such as 10 micrometers, 15 micrometers, 20 micrometers, 25 micrometers, 30 micrometers, 35 micrometers, 40 micrometers, or 45 micrometers.

In some embodiments, forming the enhanced coating on the base structure includes forming an initial coating on the base structure using a deposition process (e.g., PVD, ALD or CVD), and doping the initial coating to obtain the enhanced coating. In some embodiments, the deposition process is a high temperature deposition process, as described above. Any suitable doping process can be used to dope the initial coating to obtain the enhanced coating. Examples of doping processes include particle bombardment (e.g., helium (He) bombardment), particle implantation (e.g., ion implantation), etc. Examples of dopants that can be used to dope the initial coating include yttrium (Y), phosphorous (P), boron (B), etc. In some embodiments, the dopant is deposited at the same time as a base material (e.g., base coating).

In some embodiments, a filter includes a material that increases radical species detection resolution and measurement accuracy in a radical sensor by reducing sensor signal noise. For example, in the context of fluorine radical detection, the material can include a silicon material. Such a material can increase the radical detection rate of the filter to the radical species. The thickness range of the material can vary between 500 nanometers to about 50 micrometers. The diameter of the region coated with the material can range between about 2 millimeters to about 14 millimeters. The deposited material may have reaction rates with the target radical that are several times higher and as such the detection sensitivity is enhanced while the relative lifetime for the same coating thickness is reduced.

The radical sensor can be used to measure thickness change of the filter formed on the base structure. Thickness change expressed in terms of areal mass density (mass per unit area) may be more appropriate at subatomic sizes. For heavy loading on the base structure, accuracy of the measurement can depend on the knowledge of the shear-mode acoustic impedance value of the deposited material. Larger crystals do not have higher sensitivity. Since a radical sensor is not a weighing device as it does not require a gravitational force, a radical sensor can be used in zero gravity environments such as outer space. In some embodiments, a thickness reading of the filter, t_{f}, may be derived from the areal mass density value of the filter based on the density of the material, pf (e.g., t_{f} ρ_{f}). The areal mass density measurement is in absolute value, in some embodiments. In some embodiments, no calibration is needed for a properly designed radical sensor. Temperature variation, stress, gas adsorption and desorption, surface reaction, etc. can all give false signals.

Embodiments described herein can provide various technical benefits. For example, embodiments described herein can improve the lifespan and/or performance of radical sensors. These and other embodiments, along with many of their advantages and features, are described in more detail in conjunction with the below description and attached figures.

Although the remaining disclosure will routinely identify specific deposition and/or etch processes utilizing the disclosed technology, it will be readily understood that the systems and methods are equally applicable to other deposition, etch, and cleaning chambers, as well as processes as may occur in the described chambers. Accordingly, the technology should not be considered to be so limited as for use with these specific deposition processes or chambers alone. The disclosure will discuss one possible system and chamber that may include lid stack components according to embodiments of the present technology before additional variations and adjustments to this system according to embodiments of the present technology are described.

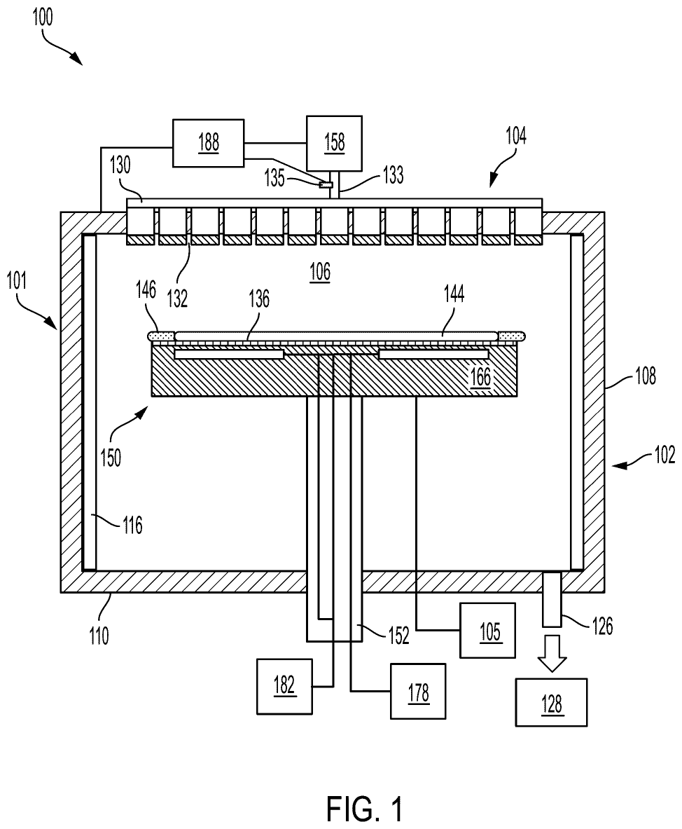

FIG. 1 is a sectional view of a manufacturing system 100, according to some embodiments. The manufacturing system 100 may include a processing chamber (“chamber”) 101 coupled to a plasma source 158 via one or more gas delivery lines 133. The chamber 101 may be, for example, a plasma etch reactor, a deposition chamber, etc. The chamber 101 may be suitable for an etching operation, a deposition operation, a chamber cleaning operation, a plasma treatment operation, or any other type of operation typical of a semiconductor manufacturing facility. In some embodiments, one or more substrates (e.g., wafers) 144 may be provided within the chamber 101. In some embodiments, chamber 101 may be maintained at a pressure suitable for the target operation. In a particular embodiment, the pressure may be between approximately a fraction of a Torr and approximately 200 Torr. The chamber 101 and/or plasma source 158 may be connected to a system controller 188, which may control processing of the plasma source 158 and/or chamber 101 (e.g., by controlling set points, loading recipes, and so on).

An acoustic resonance sensor device 135 may be connected to the gas delivery line(s) 133. The acoustic resonance sensor device 135 can include a radical sensor to detect radical species in a gas or plasma delivered by the plasma source 158. For example, the radical sensor can measure an amount or concentration of the radical species. In some embodiments, the acoustic resonance sensor device 135 is fluidically coupled to the chamber 101 and/or to the gas delivery line(s) 133. For example, a valve may be provided along a tube between the chamber 101 and the acoustic resonance sensor device 135. In some embodiments, the valve is a type of valve that allows for an unobstructed line of sight between the chamber 101 and the radical sensor. For example, the valve may be an isolation gate valve. An isolation gate valve may allow for a binary state of operation. That is, the valve may be open (i.e., 1) or closed (i.e., 0). When the valve is open, the line of sight is unobstructed. Alternately, another type of valve such as a needle valve may be used.

In some embodiments, the radical sensor includes a piezoelectric resonator. For example, the piezoelectric resonator can include a QCM resonator. A piezoelectric resonator can resonate at a resonant frequency by applying an alternating current to a base structure including a piezoelectric material. A filter can be formed on one or more surfaces of the base structure. The filter can be reactive to a narrow range of molecular species. In particular, the filter can be composed of a material that is reactive to a target molecular species of a particular target gas from among gases being used in a process. In some embodiments, the acoustic resonance sensor device 135 includes a radical sensor holder to hold the radical sensor. The acoustic resonance sensor device 135 will be described in greater detail below with reference to the proceeding figures.

In some embodiments, the plasma source 158 is a remote plasma source (RPS) that generates plasma at a remote location and delivers the externally generated plasma to the chamber 101. Alternatively, the chamber 101 may include an integrated plasma source (not shown) that can generate plasma within the processing chamber. In either instance, the radical sensor may be disposed within or connected to the chamber 101 rather than in or connected to the gas delivery lines 133 in some embodiments.

The chamber 101 can include a substrate support assembly 150. The substrate support assembly 150 can include a puck 166. The puck 166 may perform chucking operations, e.g., vacuum chucking, electrostatic chucking, etc. The substrate support assembly 150 may further include base plate, cooling plate and/or insulator plate (not shown).

The chamber 101 can include a chamber body 102 and a lid 104 that enclose an interior volume 106. The chamber body 102 may be fabricated from aluminum, stainless steel, or other suitable material. The chamber body 102 generally includes sidewalls 108 and a bottom 110. An outer liner 116 may be disposed adjacent to the sidewalls 108, e.g., to protect the chamber body 102. The outer liner 116 may be fabricated and/or coated with a plasma or halogen-containing gas resistant material. The outer liner 116 may be fabricated from or coated with aluminum oxide. The outer liner 116 may be fabricated from or coated with yttria, yttrium alloy, oxides thereof, etc.

The exhaust port 126 may be defined in the chamber body 102, and may couple the interior volume 106 to a pump system 128. The pump system 128 may include one or more pumps, valves, lines, manifolds, tanks, etc., utilized to evacuate and regulate the pressure of the interior volume 106.

The lid 104 may be supported on one of the sidewalls 108 of the chamber body 102. The lid 104 may be openable, allowing access to the interior volume 106. The lid 104 may provide a seal for the chamber 101 when closed. The plasma source 158 may be coupled to the chamber 101 to provide process, cleaning, backing, flushing, etc., gases and/or plasmas to the interior volume 106 through a gas distribution assembly 130, which can be integrated with the lid 104.

Examples of processing gases that may be used in the manufacturing system 100 include halogen-containing gases, such as F₂, C₂F₆, SF₆, SiCl₄, HBr, NF₃, CF₄, CHF₃, CH₂F₃, Cl₂ and SiF₄. Other reactive gases may include O₂ or N₂O. Non-reactive gases may be used for flushing or as carrier gases, such as N₂, He, Ar, etc. The gas distribution assembly 130 (e.g., showerhead) may include multiple apertures 132 on the downstream surface of the gas distribution assembly 130. The apertures 132 may direct gas flow to the surface of a substrate 144. In some embodiments, gas distribution assembly may include a nozzle (not pictured) extended through a hold in the lid 104. A seal may be made between the nozzle and the lid 104. The gas distribution assembly 130 may be fabricated and/or coated by a ceramic material, such as silicon carbide, yttrium oxide, etc., to provide resistance to processing conditions of the chamber 101.

The substrate support assembly 150 is disposed in the interior volume 106 below the gas distribution assembly 130. The substrate support assembly 150 holds the substrate 144 during processing. An inner liner (not shown) may be coated on the periphery of substrate support assembly 148. The inner liner 118 may share features (e.g., materials of manufacture, function, etc.) with outer liner 116.

The substrate support assembly 150 may include supporting a pedestal 152, an insulator plate, a base plate, a cooling plate, and a puck 166. The puck 166 may include electrodes 136 for providing one or more functions. For example, the electrodes 136 may include chucking electrodes (e.g., for securing the substrate 144 to an upper surface of the puck 166), heating electrodes, RF electrodes for plasma control, etc.

A protective ring 146 may be disposed over a portion of the puck 166 at an outer perimeter of the puck 166. The puck 166 may be coated with a protective layer (not shown). The protective layer may be a ceramic such as Y₂O₃ (yttria or yttrium oxide), Y₄Al₂O₉(YAM), Al₂O₃ (alumina), Y₃Al₅O₁₂ (YAG), YAlO₃ (YAP), quartz, SiC (silicon carbide), Si₃N₄ (silicon nitride), Sialon, AlN (aluminum nitride), AlON (aluminum oxynitride), TiO₂ (titania), ZrO₂ (zirconia), TiC (titanium carbide), ZrC (zirconium carbide), TiN (titanium nitride), TiCN (titanium carbon nitride), Y₂O₃ stabilized ZrO₂ (YSZ), and so on. The protective layer may be a ceramic composite such as YAG distributed in an alumina matrix, a yttria-zirconia solid solution, a silicon carbide-silicon nitride solid solution, or the like. The protective layer may be sapphire or MgAlON.

The puck 166 may further include multiple gas passages such as grooves, mesas, and other features that may be formed in an upper surface of the puck 166. Gas passages may be fluidly coupled to a gas source 105. Gas from the gas source 105 may be utilized as a heat transfer or backside gas, may be utilized for control of one or more lift pins of the puck 166, etc. Multiple gas sources may be utilized (not shown). Gas passages may provide a gas flow path for a backside gas such as He via holes drilled in the puck 166. Backside gas may be provided at a controlled pressure into gas passages to enhance heat transfer between the puck 166 and the substrate 144.

The puck 166 may include one or more clamping electrodes. The clamping electrodes may be controlled by a chucking power source 182. Clamping electrodes may further couple to one or more RF power sources through a matching circuit for maintaining a plasma formed from process and/or other gases within the chamber 101. The RF power sources may be capable of producing an RF signal having a frequency from about 50 kilohertz (kHz) to about 3 gigahertz (GHz) and a power of up to about 10,000 Watts. Heating electrodes of the puck 166 may be coupled to heater power source 178.

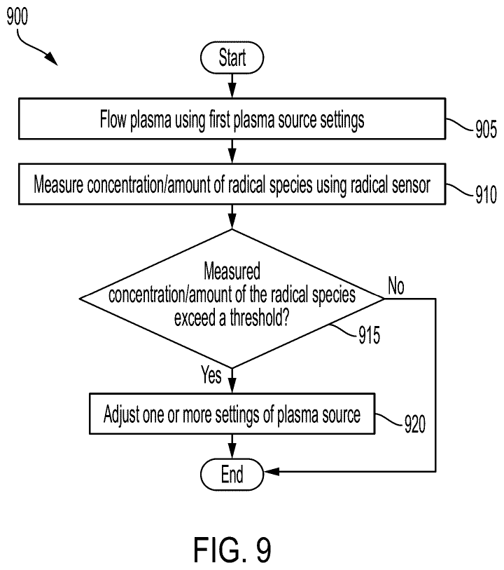

The system controller 188 may control one or more parameters and/or set points of the plasma source 158 and/or the chamber 101. The system controller 188 can be and/or include a computing device such as a personal computer, a server computer, a programmable logic controller (PLC), a microcontroller, and so on. The system controller 188 can include one or more processing devices, which can be general-purpose processing devices such as a microprocessor, central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device can also be one or more special-purpose processing devices such as an application specific integrated circuit (ASIC), a field programmable gate array (FPGA), a digital signal processor (DSP), network processor, or the like. The system controller 188 can include a data storage device (e.g., one or more disk drives and/or solid-state drives), a main memory, a static memory, a network interface, and/or other components. The system controller 188 can execute instructions to perform any one or more of the methodologies and/or embodiments described herein. The instructions can be stored on a computer readable storage medium, which can include the main memory, static memory, secondary storage and/or processing device (during execution of the instructions). In some embodiments, execution of the instructions by the system controller 188 causes the system controller 188 to perform methods, such as the methods described below with reference to FIG. 9. For example, the system controller 188 may receive measurements from radical sensor indicating a concentration of a particular species of radical species in a received or generated plasma, and may adjust one or more properties or settings (e.g., such as a plasma power) of the plasma source 158 responsive to the measured radical concentration. The system controller 188 can also be configured to permit entry and display of data, operating commands, and the like by a human operator.

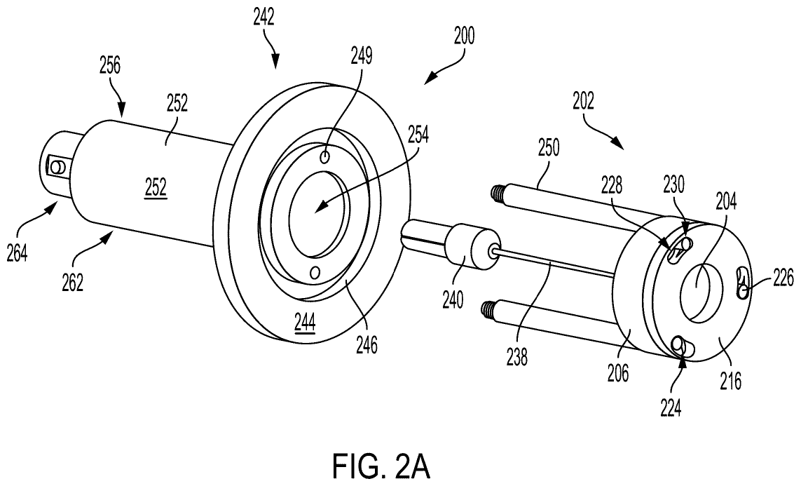

FIGS. 2A-2B illustrate an example acoustic resonance sensor device for radical species detection (“device”) 200, in accordance with some embodiments. The device 200 may can be disposed within a processing region of a deposition chamber, etch chamber, or other type of chamber, such as chamber 101 of manufacturing system 100 of FIG. 1.

The device 200 may include a radical sensor holder 202, which may be sized and shaped to receive a radical sensor 204. In some embodiments, the radical sensor 204 includes a piezoelectric resonator. For example, the radical sensor 204 can include a QCM resonator.

For example, the radical sensor holder 202 may include a body 206 that defines a recess 208 and an aperture 210. The radical sensor 204 may include a disc body 212 and may include a stem 214 extending from the disc body 212. The disc body 212 may be circular or otherwise round in some embodiments, although other shapes are possible. The disc body 212 may be seated within a recess 208, while the stem 214 may extend through an aperture 210.

In some embodiments, electrically conductive resilient members 222 (such as springs) may be positioned above and/or below the disc body 212 to help maintain electrical contact between the radical sensor 204 and the radical sensor holder 202, while ensuring that pressure between a lid 216 and the body 206 does not crack or otherwise damage the radical sensor 204. In some embodiments, the electrically conductive resilient members 222 may be formed from and/or coated with chamber-compatible materials to ensure that the electrically conductive resilient members 222 do not corrode during exposure to process gases and plasma radical species. In some embodiments, the electrically conductive resilient members 222 may be formed from and/or coated with a corrosion-resistant material. For example, the electrically conductive resilient members 222 can be formed from palladium (Pd), although other materials may be used in various embodiments.

In some embodiments, the body 206 is in-line. In some embodiments, the body 206 is configured to be tilted in accordance with a range of angles relative to the vertical axis. In some embodiments, the body 206 can be tilted between about 0 degrees to about 90 degrees relative to the vertical axis. In some embodiments, the body 206 can be tilted about 45 degrees relative to the vertical axis.

The lid 216 may be coupled with body 206 to secure the radical sensor 204 within a recess 208. The lid 216 may include an inner portion 218 that may extend into a recess 208 and may press against the radical sensor 204 and/or the electrically conductive resilient members 222 that may be disposed between the lid 216 and the radical sensor 204. The lid 216 may also include a flange 220 that is coupled with the inner portion 218. The flange 220 may be positioned against an upper surface of the body 206. The flange 220 may include slots 224 that may receive fasteners 226 that secure the lid 216 to the body 206. In some embodiments, the fasteners 226 may be screws. However, when the body 206 is formed from aluminum alloys, screws may be undesirable due to the nature of aluminum threads to wear over time. In such embodiments, other fasteners, such as press-fit connections, may be utilized as the fasteners 226. For example, each slot 224 may be generally arcuate in shape and may be keyed. In the present embodiment, each slot 224 may include a receiving end 228 and a locking end 230. The receiving end 228 may be wider than the locking end 230. For example, medial and/or bottom portion of each slot may taper to a narrower width along a length of each slot 224 to form the locking end 230 having a shelf 232. In some embodiments, an upper portion of each slot 224 may have a constant width. The fasteners 226 may each be a pin having an elongate pin body 234 that couples with a pin head 236 having a greater diameter than the pin body 234. Each pin body 234 may be secured within the body 206, such as by being press fit within a recess formed within the body 206, with each respective pin head 236 extending above and being spaced apart from an upper surface of the body 206. The lid 216 may be positioned atop the body 206 with each pin head 236 extending through the receiving end 228 of respective slot 224. The lid 216 may then be rotated relative to the body 206 to slide each pin head 236 toward and into engagement with the locking end 230 of each slot 224 to secure the lid 216 against the body 206. In such a position, a bottom surface of each pin head 236 may be seated against a shelf 232, which prevents the lid 216 from being pulled away from the body 206 until rotated in the opposite direction to align each pin head 236 with the receiving end 228 of respective slot 224. Such a configuration may enable the lid 216 to be repeatedly removed from and resecured to the body 206 to insert and/or remove the radical sensor 204 from the recess 208.

The radical sensor 204 may include a crystalline material, such as a polycrystalline material, that may react with radical species (e.g., plasma radical species). The reaction with the radical species may result in the additional or removal of a small amount of mass of the crystalline material and/or filter, such as due to oxide growth/decay and/or a film deposition on the surface of the radical sensor 204. The mass change may alter the frequency of the radical sensor 204. The frequency may be measured and correlated to plasma radical concentration values, which may enable the radical sensor 204 to be effectively used to monitor (e.g., detect and/or measure) radical species within a processing region of a chamber. The radical sensor 204 may be formed from various quartz crystals, such as, but not limited to, SiOₓ.

The radical sensor holder 202 may be formed from an electrically conductive and/or chamber compatible material. In some embodiments, an entirety of the radical sensor holder 202 is formed from, or coated with, an electrically conductive chamber compatible material. In some embodiments, the radical sensor holder 202 includes Al. For example, the radical sensor holder 202 can include an Al alloy. In some embodiments, an Al alloy includes magnesium, such as between 5% and 20% by mass of magnesium, which may provide enhanced corrosion resistance (e.g., when fluorinated during processing operations). In some embodiments, aluminum 5083 and/or aluminum 6061 may be used, although other aluminum alloys may be utilized in various embodiments. The use of aluminum may also provide a large surface area of thermally conductive material in contact with the radical sensor 204 and thereby reduce acoustic resonance shifts due to thermal effects.

The device 200 may include an electrical transmission line 238 that may be electrically coupled with the radical sensor 204. For example, the stem 214 may define a recess 241 that may receive an end of the electrical transmission line 238. In some embodiments, the end of the electrical transmission line 238 may be secured within the stem 214 using a set screw, however other securement techniques are possible in various embodiments. An opposite end of the electrical transmission line 238 may be secured within a first end of an adapter 240, such as by using an additional set screw to secure the opposite end of the electrical transmission line 238 into a recess formed in the first end of the adapter 240. In some embodiments, the electrical transmission line 238 is formed from aluminum. In some embodiments, the electrical transmission line 238 provides tension release (e.g., slack) between adapter 240 and the stem 214. For example, the tension release provided by the electrical transmission line 238 can enable proper functionality of the electrically conductive resilient members 222. As another example, if the electrical transmission line 238 is too rigid, there is a risk of disconnection with respect to the adapter 240.

The radical sensor holder 202 and at least a portion of the electrical transmission line 238 may be designed to be exposed to the processing region of a chamber. To help mount holder within the chamber, the device 200 may include an exterior portion 242, which may be positioned outside of the processing region. For example, the exterior portion 242 may be disposed against an outer wall of a chamber body, liner assembly, and/or other component of the chamber that defines a portion of the processing region. The component may define a small aperture through which the radical sensor holder 202 may be inserted. Exterior portion 242 may include a flange 244 having a greater diameter than the radical sensor holder 202. The flange 244 may be positioned against an outer surface of the chamber component defining the aperture, and may prevent the remaining parts of the exterior portion 242 from being inserted within the chamber. The flange 244 may have vacuum sealing in circular shape or non-circular shape depending on matching flange on the process chamber or vacuum system. The flange 244 may define an annular recess 246. An annular sealing member 248 may be seated within the annular recess 246 and may be used to provide a vacuum seal for an interface between the flange 244 and a chamber component that the flange 244 is positioned against. The flange 244 may define connectors 249, such as threaded connectors. Each of the connectors 249 may receive an end of a respective one of standoffs 250. The standoffs 250 may extend between and couple the radical sensor holder 202 and the flange 244. The standoffs 250 may be removably coupled with the flange 244 and/or the radical sensor holder 202, such as via threaded connections. In some embodiments, ends of each of the standoffs 250 may be permanently coupled with one of the radical sensor holder 202 or the flange 244. The connectors 249 and the standoffs 250 may be disposed radially inward of an annular recess 246, which may ensure that an annular sealing member 248 is able to seal an area radially outward of the connectors 249 and the standoffs 250.

The exterior portion 242 may include a connector 256 having a housing 252 that extends from the flange 244 in a direction opposite of the radical sensor holder 202. The housing 252 and the flange 244 may collectively define a central aperture 254 that extends through an entire length of the exterior portion 242. The housing 252 may include a housing shoulder 258 that extends radially inward from an inner sidewall 260 of the housing 252. The housing shoulder 258 may define a portion of a central aperture 256, with the portion of the central aperture 256 that passes through the housing shoulder 258 having a smaller diameter than the rest of the central aperture 256. In some embodiments, the housing 252 may include first housing portion 262 and a second housing portion 264 that are coupled together, either permanently or reversibly (e.g., using a threaded connection). For example, the first housing portion 262 may extend from the flange 244 and may define the housing shoulder 258. The second housing portion 264 may be coupled with a distal end of the first housing portion 262 and may define a coupling mechanism for coupling the device 200 with a coupling mechanism of an electrical port, such as a Bayonet Neill-Concelman (BNC) connection. The first housing portion 262 and the second housing portion 264 may be reversibly coupled with one another to enable interior components, such as an isolator 266, to be inserted and secured within an interior of the housing 252.

The adapter 240 and one end of the electrical transmission line 238 may be disposed within the central aperture 256. A second end of the adapter 240 may define an additional recess that may receive a first end of the electrical connection 268. A second end of the electrical connection 268 may include a connection member 271, such as a BNC bayonet that may be inserted within a corresponding electrical port of a chamber. The electrical connection 268 and the electrical transmission line 238 may be used to electrically couple the radical sensor 204 with the chamber electrical port for transmission of electrical signals between the radical sensor 204 and chamber electronics. In some embodiments, a medial portion of the electrical connection 268 may include a flange 270 that extends radially outward from a body of the electrical connection 268. The flange 270 may be positioned in alignment or a slight offset with the housing shoulder 258. The isolator 266 may define an aperture 273 through which a portion of the electrical connection 268 may pass. A first end of the isolator 266 may be seated against a rear surface of the housing shoulder 258 and a rear surface of the flange 270. In some embodiments, the first end of the isolator 266 may be a single planar surface, such as when rear surfaces of the housing shoulder 258 and the flange 270 are in substantial alignment. In other embodiments, the first end of the isolator 266 may include a stepped interface, such that an outer portion of the first end protrudes beyond an inner portion of the first end. Such a configuration may enable an offset between rear surfaces of the housing shoulder 258 and the flange 270. Sealing members 272 may be disposed between the first end of the isolator 266 and rear surfaces of each of the housing shoulder 258 and the flange 270. For example, a first sealing member 272a may be disposed between the first end of the isolator 266 and a rear surface of the housing shoulder 258 and a second sealing member 272b may be disposed between the first end of the isolator 266 and a rear surface of the flange 270. In some embodiments, each sealing member 272 may be an O-ring, gasket, or other compressible sealing element. Each sealing member 272 can be formed from an elastomeric polymer and/or chamber-compatible material.

Compression of the sealing members 272 may provide a vacuum seal within the interior of the central aperture 254 and may enable the radical sensor holder 202 to be positioned within a low pressure/vacuum environment while an exterior portion 242 remains at higher (e.g., atmospheric) pressures. To ensure that the sealing members 272 are sufficiently compressed, the device 200 may include an adjustment mechanism that enables an amount of compressive force applied to the sealing members 272 to be controlled. In the illustrated embodiment, the adjustment mechanism may include threads 274 formed on a shaft 280 of the electrical connection 268. A nut 278 may be threadingly engaged with the threads 274 such that as the nut 278 is tightened, the nut 278 moves toward and contacts a second end of isolator to force the isolator 266 toward the flange 270, the housing shoulder 258, the flange 244, and the radical sensor holder 202. Movement of the isolator 266 in this direction causes the sealing members 272 to be compressed to create a vacuum seal between the isolator 266, the housing 252, and the electrical connection 268. In some embodiments, the nut 278 may be secured to the threads 274 and tightened prior to coupling the second housing portion 264 with the first housing portion 262, which may provide additional clearance for a wrench or other tool to manipulate the nut 278. Once the nut 278 is tightened, the second housing portion 264 may be secured to the first housing portion 262, such as by engaging threaded connectors of each housing portion. In some embodiments, a proximal/inner end of the second housing portion 264 may be disposed within the central aperture 254 and may contact the second end of the isolator 266. In some embodiments, the second end of isolator 266 may be a single planar surface such that when nut 278 and the second housing portion 264 are tightened, the nut 278 and the second housing portion 264 are in substantial alignment. In other embodiments, the second end of the isolator 266 may include a stepped interface, such that an inner portion of the second end protrudes beyond an outer portion of the second end. Such a configuration may accommodate an offset between surfaces of the nut 278 and the second housing portion 264.

The isolator 266 may be formed from an electrically insulting material, such as a dielectric or ceramic material (e.g., alumina). Such materials may ensure that the isolator 266 may support the electrical connection 268 within a center of the central aperture 254 while insulating the housing 252 from the electrical connection 268 to ensure that there is no shorting or transmission of electrical signals between the electrical connection 268 and the housing 252. Other than the isolator 266, the exterior portion 242 may be formed from and/or coated with a chamber compatible material, such as an aluminum alloy, as portions of the interior of exterior portion that are between the sealing members 272 and the flange 244 may be exposed to process gases, radical species, and/or low pressure environments. In some embodiments, at least a portion of the exterior portion 242 (aside from the isolator 266) may be formed from and/or coated with a same material as the radical sensor holder 202, although other materials are possible in various embodiments.

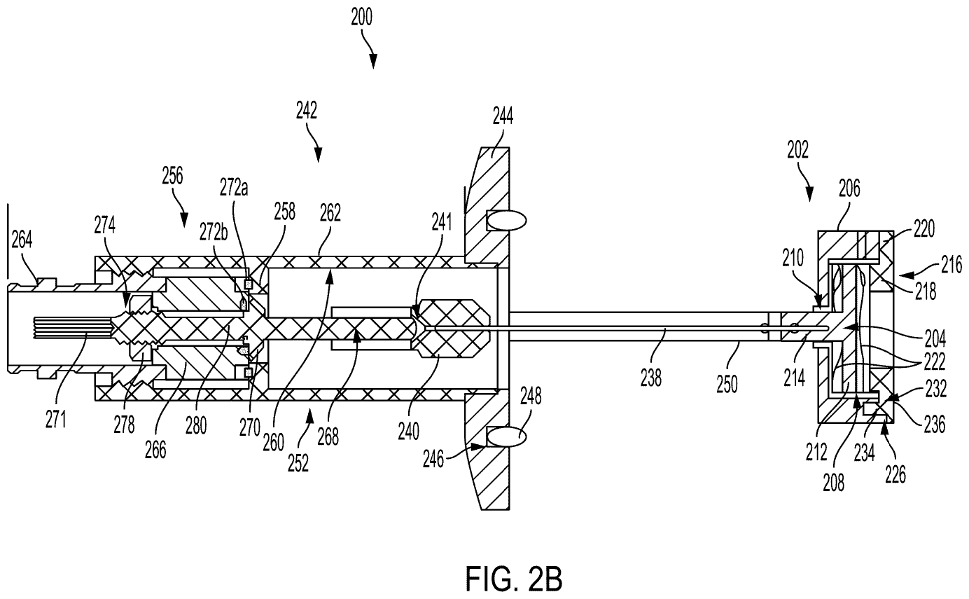

FIGS. 3A-3D illustrate an example radical sensor 300, in accordance with embodiments of the present disclosure. In some embodiments, the radical sensor 300 corresponds to the radical sensor 204 of FIGS. 2A-2B. FIG. 3A is a sectional side view of the radical sensor 300, according to some embodiments. FIG. 3B is a back view of the radical sensor 300 of FIG. 3A, according to some embodiments. FIG. 3C is a front view of the radical sensor 300 of FIG. 3A, according to some embodiments.

In some embodiments, the radical sensor 300 includes a piezoelectric resonator. For example, the radical sensor 300 can include a QCM resonator. As shown, the radical sensor 300 can include a base structure including a radical sensor base 315. In some embodiments, the radical sensor 300 includes a piezoelectric resonator and the radical sensor base 315 includes a piezoelectric material that can oscillate at certain resonant frequencies. The radical sensor base 315 may include a thin plate of a piezoelectric crystal (e.g., quartz crystal) that oscillates in the thickness-shear mode because the radical sensor base 315 is sensitive to mass change on the crystal. The piezoelectric nature of the crystal allows the crystal to be driven into oscillation and with its resonant frequency measured by simple electrical means. In some embodiments, the crystal is precisely cut at certain angles with respect to its crystallographic axes. By increasing the mass of the vibrating unit, the typical result is the decrease of that solid material's resonant frequencies.

As shown in FIGS. 3A-C, the radical sensor base 315 can have a flat face and a convex face. The flat face may be a front face and the convex face may be a back face. As shown, the base structure can further include a back electrode 320 and a front electrode 330. For example, in this example, the flat face may be covered by the front electrode 330 and the convex face may be covered by the back electrode 320. In some embodiments, the back electrode 320 includes a back electrode edge 325 connected to a back electrode center 320 via one or more electrode bridges 327. This configuration enables an alternating current to be applied to and/or read from the electrodes without compromising the ability of the radical sensor base 315 to oscillate freely. A sensing surface of the radical sensor 300 may be a center region of the front face (e.g., a center region of the front electrode 330).

In some embodiments, the sensing surface of the radical sensor 300 is coated with a filter 335 that is sensitive to reaction with a particular molecular species of a target gaseous species. The composition of the filter 335 may depend on the application for which the radical sensor 300 will be used. In some embodiments, the filter 335 includes a coating (e.g., film).

In some embodiments, the filter 335 is composed of a material that reacts with a radical molecular species of a target gas, but that does not react to stable molecular species of the target gas. For example, the material of the filter 335 may react to fluorine radical species, but may not react to stable molecules containing fluorine (e.g., F₂, C₂F₆, SF₆, NF₃, CF₄, CHF₃, CH₂F₃, etc.). The material of the filter 335 may also not react to other molecules that may be included in a gas flow, whether those other molecules are radical species or stable molecular species. For example, the material of the filter 335 may react to fluorine radical species, but may not react to carbon radical species, nitrogen radical species, hydrogen radical species, etc. Alternatively, the material may only react to hydrogen radical species, or may only react to carbon radical species, or may only react to some other radical species.

In some embodiments in which the radical sensor 300 is tuned to detect fluorine radical species, the filter 335 includes silicon dioxide (SiO₂), tungsten, or a tungsten oxide (e.g., tungsten (III) oxide or W₂O₃) and/or organic materials (such as photoresist). In some embodiments in which the radical sensor is tuned to detect fluorine radical species, the filter 335 includes a transition metal that selectively reacts with fluorine radical species. In some embodiments in which the radical sensor is tuned to detect hydrogen radical species, the filter 335 comprises a polymer of carbon and hydrogen. One example of a polymer that may be used is polymethyl methacrylate (PMMA). In some embodiments in which the radical sensor is tuned to detect nitrogen radical species, the filter 335 includes a fluorinated polymer.

In some embodiments, the target radical species react with the filter 335 to form a gas, which consumes a portion of the filter 335. The consumption of the portion of the filter 335 reduces the number of molecules of the filter 335, and thus reduces an overall mass of the film of the filter 335. This reduction in mass may be detected by the radical sensor 300 on which the filter 335 has been formed.

In some embodiments, the reaction of the target radical species with the filter 335 produces a solid byproduct. The solid byproduct can adhere to the filter 335, which can increase the mass of the filter 335. This increase in mass may be detected by the radical sensor 300 on which the filter 335 has been formed.

In some embodiments, the reaction of the target radical species with the filter 335 is an absorption process where the filter 335 absorbs the target radical species. The absorption of the radical species causes the mass of the filter 335 to increase. Once the filter 335 becomes saturated with the target radical species and/or between process runs, a purge or cleaning process may be performed to cause the radical species to desorb from the filter 335. In an example, a QCM with a coating of PMMA may be used to detect fluorine radical species. The PMMA may absorb fluorine radical species, and the mass change of the film caused by absorption of the fluorine radical species may be detected by a change in resonant frequency of radical sensor 300. The fluorine radical species may then be desorbed by flowing another gas such as argon across radical sensor 300.

In some embodiments, the filter 335 has a thickness of about 1-100 micrometers. In some embodiments, the filter 335 has a thickness of about 30-40 micrometers. Other thicknesses, such as 10, 20, 30, 40, 50, 60, 70, 80 or 90 micrometers may also be used for the filter 335.

In some embodiments, the filter 335 is a coating. In some embodiments, forming filter 335 includes forming the coating using a high temperature deposition process. A coating formed using a high temperature deposition process can exhibit decreased etch rates when exposed to a radical species as compared to a coating formed using other deposition processes. In some embodiments, the high temperature deposition process is performed at a temperature that ranges from about 150° C. to about 450° C. Examples of deposition processes that can be used to perform a high temperature deposition process include PVD (e.g., magnetic sputtering or electron beam evaporation), ALD, CVD, plasma spray, IAD, etc.

In some embodiments, the filter 335 includes a thick coating formed using a deposition process. In some embodiments, the deposition process is a high temperature deposition process, as described above. A thicker coating can increase the lifespan of the radical sensor 300. However, too thick of a coating can negative impact performance of the radical sensor 300 by blocking the transmission of acoustic waves. Thus, the thickness of the coating can be optimized to balance lifespan with performance. In some embodiments, the coating of the filter 335 has a thickness that ranges between about 5 micrometers to about 50 micrometers.

In some embodiments, the filter 335 includes a doped coating. For example, forming the filter 335 can include forming an initial coating on the base structure using a deposition process (e.g., PVD, ALD or CVD), and doping the initial coating with a dopant to obtain the filter 335. In some embodiments, the deposition process is a high temperature deposition process, as described above. Any suitable doping process can be used to dope the initial coating to obtain the enhanced coating. Examples of doping processes include particle bombardment (e.g., He bombardment), particle implantation (e.g., ion implantation), etc. Examples of dopants that can be used to dope the initial coating include Y, P, B, etc. In some embodiments, a base material (e.g., base coating) and the dopant are deposited at substantially the same time to form the filter 335.

In some embodiments, the filter 335 includes a material that increases radical species detection resolution and measurement accuracy of the radical sensor 300 by reducing sensor signal noise. Such a material can increase the radical detection rate of the filter 335 to the radical species. The thickness range of the material can vary between 500 nanometers to about 50 micrometers. The diameter of the material can range between about 2 millimeters to about 14 millimeters. For example, in the context of fluorine radical detection, the material can be a silicon material.

In some embodiments, the filter 335 includes a crystalline material. For example, the crystalline material can be formed on the front electrode 330. In some embodiments, the crystalline material is a polycrystalline material. In some embodiments, the crystalline material includes SiO₂.

An interface between the crystalline material and the base structure can be a high-quality interface to enable an acoustic wave to travel through the interface. For example, a high-quality interface can be an interface having a suitable porosity. In some embodiments, a high-quality interface has a porosity of less than or equal to about 20%, a porosity of less than or equal to about 30%, or a porosity of less than or equal to 40%.

In some embodiments, the crystalline material is cut from a base material. For example, the crystalline material can include a SiO₂ crystal (e.g., polycrystalline SiO₂) cut from a base quartz material. In some embodiments, the crystalline material has a thickness that ranges from about 5 micrometers to about 50 micrometers.

In some embodiments, forming the crystalline material on the base structure includes attaching the crystalline material to the base structure (e.g., the front electrode 330). For example, forming the crystalline material on the base structure can include using a bonding layer to attach the crystalline material to a surface of the base structure (e.g., a surface of the front electrode 330). The bonding layer can have suitable properties to enable an acoustic wave to penetrate through an interface.

In some embodiments, the filter 335 includes a crystal structure having a number of grains. In some embodiments, a grain has a microstructure grain size selected to achieve a target filter lifetime depending on process conditions within which the radical sensor 300 operates. In some embodiments, the microstructure grain size ranges between about 100 nanometers to about 50 micrometers. Additionally, increasing grain boundary size can increase the activation energy needed to induce a chemical reaction. Therefore, increasing grain boundary size can result in a greater amount or concentration of radical species being needed before seeing etching of the material of the filter 335.

In some embodiments, the radical sensor 300 shown in FIGS. 3A-3C measures radical species without respect to charge. In some embodiments, it may be advantageous to measure only neutral radical species or only radical species having a particular charge.

FIG. 3D is a sectional side view of the radical sensor 300 of FIG. 3A with the addition of a charged grating or grid 352, according to some embodiments. The charged grating or grid 352 may be disposed in front of the front face of the radical sensor 300 to measure only neutral radical species of a particular molecular species. The charged grating or grid 352 may include a stack of meshes (e.g., wire meshes) that have particular charge. In some embodiments, as shown, a first grating or mesh is positively charged, a second grating or mesh may be grounded, and a third grating or mesh may be negatively charged. The positively charged mesh or grating may repel positively charged molecules or ions and the negatively charged mesh or grating may repel negatively charged molecules or ions. As a result, the only molecules that reach the filter 335 may be neutral molecules. Of the neutral molecules that reach the filter 335, only the radical species of a particular gaseous species may actually react with the filter 335.

In some embodiments, in order to measure an amount of positively and/or negatively charged radical species, a pair of radical sensors may be used. A first radical sensor may include the charged gratings or grids, and a second radical sensor may not include the charged gratings or grids. All radical species of a target gaseous species may be detected by the second radical sensor, and only neutral radical species of the target gaseous species may be detected by the first radical sensor. A difference between the measurements of the two radical sensors may then be computed to determine an amount of the radical species detected by the second radical sensor that were attributable to charged radical species. The grating may be modified to only filter out positively charged molecules/ions or to only filter out negatively charged molecules. Accordingly, by combining two or more radical sensors, each with a different grating configuration (e.g., one not including any grating), an amount of positively charged radical species may be detected, an amount of negatively charged radical species may be detected, and/or an amount of neutral radical species may be detected.

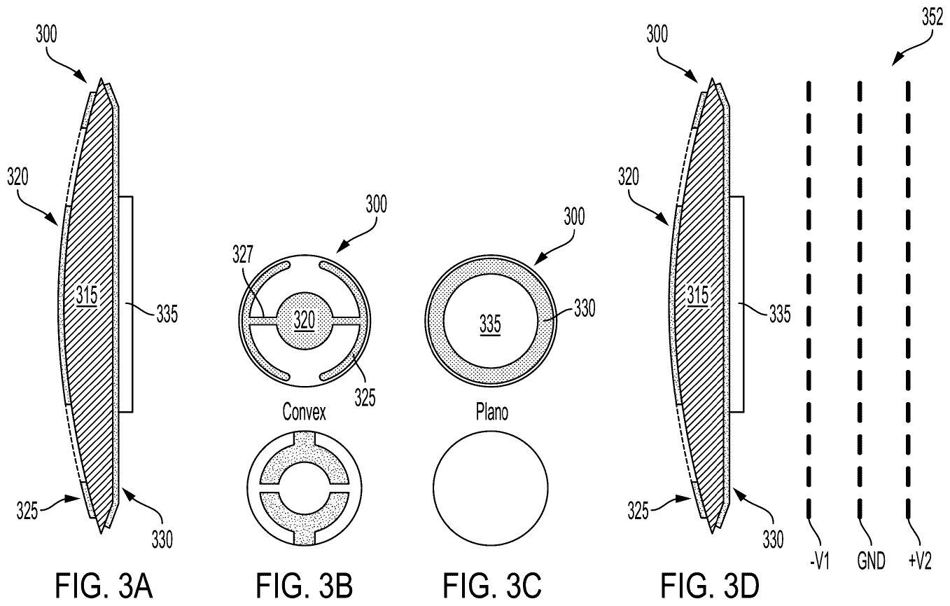

FIGS. 4A-4B are diagrams 400A and 400B illustrating the formation of a radical sensor of a radical sensor device, in accordance with embodiments of the present disclosure. In some embodiments, the radical sensor corresponds to the radical sensor 204 of FIGS. 2A-2B and/or the radical sensor 300 of FIGS. 3A-3D. In some embodiments, the radical sensor includes a piezoelectric resonator. For example, the radical sensor can include a QCM resonator.

As shown in FIG. 4A, a radical sensor can include a base structure 405 including a radical sensor base 415 (e.g., piezoelectric layer), a back electrode 420, a back electrode edge 425 and a front electrode 430, similar to the radical sensor base 315 and the electrodes 320, 325 and 330 as described above with reference to FIGS. 3A-3D. In some embodiments, the front electrode 330 has a thickness that ranges between about 5 micrometers to about 30 micrometers.

As further shown, the radical sensor can include a filter 435 formed on a layer 432. The filter 435 can be sensitive to reaction with a particular molecular species of a target gaseous species. The composition of the filter 435 may depend on the application for which the radical sensor will be used. In some embodiments, the filter 435 is composed of a material that reacts with a radical molecular species of a target gas, but that does not react to stable molecular species of the target gas. For example, the material of filter 410A may react to fluorine radical species, but may not react to stable molecules containing fluorine (e.g., F₂, C₂F₆, SF₆, NF₃, CF₄, CHF₃, CH₂F₃, etc.). The material of the filter 435 may also not react to other molecules that may be included in a gas flow, whether those other molecules are radical species or stable molecular species. For example, the material of the filter 435 may react to fluorine radical species, but may not react to carbon radical species, nitrogen radical species, hydrogen radical species, etc. Alternatively, the material may only react to hydrogen radical species, or may only react to carbon radical species, or may only react to some other radical species.

In some embodiments, the filter 435 includes a crystalline material. In some embodiments, the crystalline material is a polycrystalline material. In some embodiments, the crystalline material includes SiO₂. In some embodiments, the filter 435 has a thickness that ranges from about 5 micrometers to about 80 micrometers. In some embodiments, the filter 435 has a diameter that ranges from about 4 millimeters to about 12 millimeters. In some embodiments, the layer 432 includes the same material as the front electrode 430 (e.g., Al). In some embodiments, the layer 432 has a thickness that ranges between about 5 micrometers to about 30 micrometers.

In some embodiments, the crystalline material of the filter 435 is cut from a base material. For example, the crystalline material can include a SiO₂ crystal (e.g., polycrystalline SiO₂) cut from a base quartz material. In some embodiments, the crystalline material has a thickness that ranges from about 5 micrometers to about 50 micrometers.

In some embodiments, the filter 435 includes a crystal structure having a number of grains. In some embodiments, a grain has a microstructure grain size selected to achieve a target filter lifetime depending on process conditions within which the radical sensor operates. In some embodiments, the microstructure grain size ranges between about 100 nanometers to about 50 micrometers. Additionally, increasing grain boundary size can increase the activation energy needed to induce a chemical reaction. Therefore, increasing grain boundary size can result in a greater amount or concentration of radical species being needed before seeing etching of the material of the filter 435.

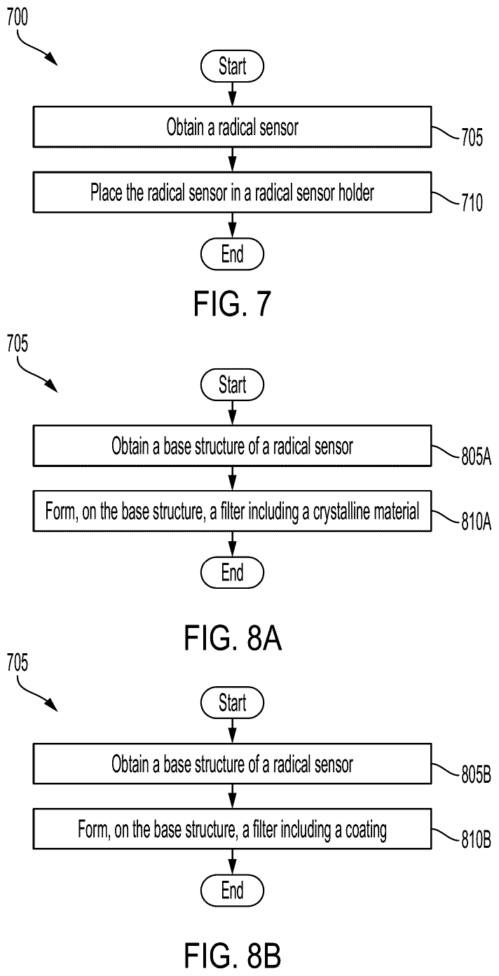

In some embodiments, and as shown, a process 437 can be performed to attach or bond the layer 432 to the front electrode 430. For example, the process 437 can include using a bonding layer or adhesive (e.g., glue) to bond the layer 432 to the front electrode 430. The bonding layer can have suitable properties to enable an acoustic wave to penetrate through an interface. Further details regarding the process 437 are described above with reference to FIGS. 3A-3D and will be described in further detail below with reference to FIGS. 7-8B.

As shown in FIG. 4B, the processing of attaching or bonding the base structure 405 to the layer 432 can result in an interface 439 between the filter 435 and the base structure 405. The interface 439 can be a high-quality interface to enable an acoustic wave to travel through the interface 439. For example, the interface 439 can have a suitable porosity. In some embodiments, a high-quality interface has a porosity of less than or equal to about 20%, a porosity of less than or equal to about 30%, or a porosity of less than or equal to 40%. Further details regarding the interface 439 are described above with reference to FIGS. 3A-3D and will be described in further detail below with reference to FIGS. 7-8B.

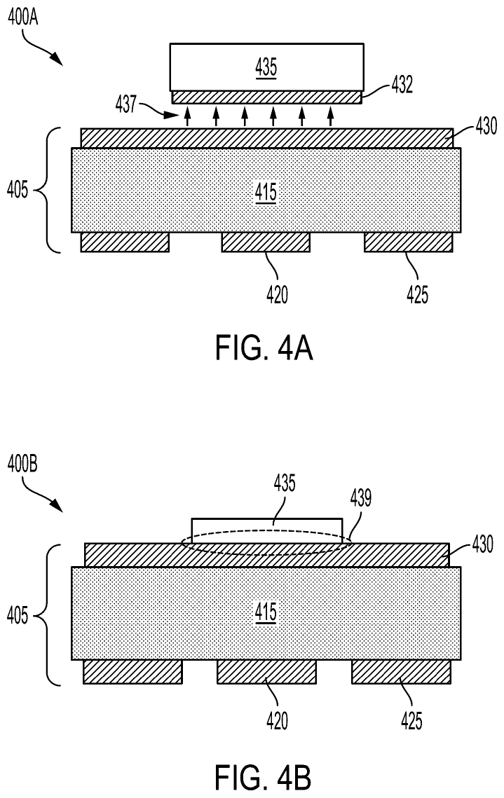

FIG. 5 illustrates an example radical sensor 500, in accordance with embodiments of the present disclosure. In some embodiments, the radical sensor 500 corresponds to radical sensor 204 of FIGS. 2A-2B. In some embodiments, the radical sensor 500 includes a piezoelectric resonator. For example, the radical sensor 500 can include a QCM resonator. As shown, the radical sensor 500 can include a base structure including a radical sensor base 515, a back electrode 520 and a back electrode edge 525, similar to those described above with reference to FIGS. 3A-3D.

Additionally, the radical sensor 500 can include a mesh 530 formed on the radical sensor base 515. In some embodiments, the mesh 530 is formed by placing the mesh 530 on the surface of the radical sensor base 515. In some embodiments, the mesh 530 is formed by depositing the mesh 530 on the surface of the radical sensor base 515. The mesh 530 can include any suitable material in accordance with embodiments described herein. Examples of suitable materials include Al, Au, Ni, etc. In some embodiments, the mesh 530 has an approximately 30% opening. In some embodiments, a thickness of the mesh 530 is less than or equal to about 5 millimeters. In some embodiments, a thickness of the mesh 530 is less than or equal to about 3 millimeters. Exposed regions 535 of the radical sensor base 515 can thus react with a radical species. Further details regarding the radical sensor 500 are described above with reference to FIGS. 3A-3D and will be described in further detail below with reference to FIGS. 7-8B.

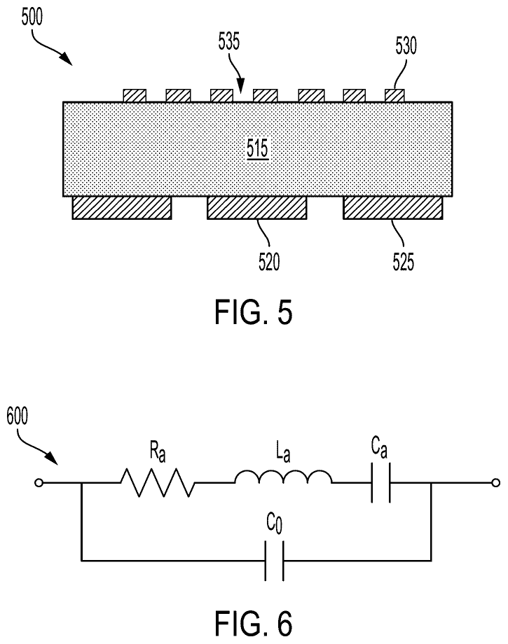

A radical sensor including a piezoelectric resonator (e.g., QCM resonator) can be represented by a simple equivalent circuit 600 for electrical analysis, as shown in FIG. 6. The mechanical behavior of the radical sensor can be represented by an electrical equivalent model as shown. This is the so-called the Butterworth van Dyke (BVD) electrical model. In the motional arm (the upper branch) of the BVD model, it consists of three components that determine the series resonance frequency of the quartz crystal plate. Rₐ corresponds to the energy dissipation due to mechanical coupling between the crystal and its holder. For some applications, added mass load on the crystal surface also causes Rₐ to increase. Lₐ corresponds to the mass being displaced during oscillation. For some applications, the total mass includes that of the crystal, the electrodes, and the deposited thin film materials. Cₐ corresponds to the stored energy in the piezoelectric resonator that is related to the elastic properties of quartz, electrodes, and the deposited materials. The parasitic capacitance Co represents the total static capacitances of the crystal electrodes, the radical sensor holder, and the connecting cable.

FIG. 7 is a flow chart of a method 700 for manufacturing an acoustic resonance sensor device for radical species detection, in accordance with some embodiments. At block 705, a radical sensor is obtained. At block 710, the radical sensor is placed in a radical sensor holder.

For example, obtaining the radical sensor at block 705 can include forming a filter on a base structure of the radical sensor. The base structure can include a piezoelectric material (e.g., quartz material). In some embodiments, the filter is formed directly on the piezoelectric material. In some embodiments, the base structure further includes a front electrode corresponding to a sensing surface of the radical sensor, and forming the filter on the base structure includes forming the filter on front electrode. The filter may be composed of a material that is selectively reactive to radical species of a target gaseous species, but that is not reactive to stable molecules of the particular gaseous species, and that is not reactive to stable molecules or radical species of other gaseous species that will be used together with the target gaseous species. In some embodiments, the filter includes a crystalline material. Further details regarding forming a filter including a crystalline material will be described herein below with reference to FIG. 8A. In some embodiments, the filter includes a coating. Further details regarding forming a filter including a coating will be described herein below with reference to FIG. 8B. Further details regarding blocks 705 and 710 are described above with reference to FIGS. 2A-6 and will now be described in further detail below with reference to FIGS. 8A-8B.

FIG. 8A is a flow chart of a method 705 for obtaining a radical sensor, in accordance with some embodiments. At block 805A, a base structure of a radical sensor is obtained and, at block 810A, a filter including a crystalline material is formed on the base structure. In some embodiments, the radical sensor includes a piezoelectric resonator and the base structure includes a piezoelectric material. In some embodiments, the piezoelectric material includes a crystal (e.g., quartz). The filter can selectively react with a radical species and a resonant frequency of the radical sensor can change in response to reaction of the radical species to the filter. In some embodiments, the crystalline material includes SiO₂. For example, the crystalline material can be a polycrystalline material. In some embodiments, the crystalline material includes a grain having a grain size that ranges from about 100 nanometers to about 50 micrometers. The grain size can be selected to achieve a target filter lifetime depending on process conditions within which the radical sensor operates. Additionally, increasing grain boundary size can increase the activation energy needed to induce a chemical reaction. Therefore, increasing grain boundary size can result in a greater amount or concentration of radical species being needed before seeing etching in the coating.

In some embodiments, forming the filter includes forming the crystalline material directly on the piezoelectric material. For example, forming the crystalline material directly on the piezoelectric material can include etching the piezoelectric material using a mesh formed on the piezoelectric material. In some embodiments, the mesh is deposited on the piezoelectric material. In some embodiments, the mesh is placed on the piezoelectric material. The mesh can include any suitable material in accordance with embodiments described herein. Examples of suitable materials include, Al, Au, Ni, etc.

In some embodiments, the base structure further includes a front electrode and a back electrode formed on the piezoelectric material. In some embodiments, forming the filter includes attaching or bonding the crystalline material to the front electrode. For example, forming the crystalline material on the base structure can include using a bonding layer (e.g., glue) to attach the crystalline material to a surface of the front electrode. The bonding layer can have suitable properties to enable an acoustic wave to penetrate through an interface. The front electrode and the back electrode can each include any suitable material in accordance with embodiments described herein. Examples of suitable materials include, Al, Au, etc. Further details regarding blocks 705A and 710A are described above with reference to FIGS. 2A-6.

FIG. 8B is a flow chart of a method 705 for obtaining a radical sensor, in accordance with some embodiments. At block 805B, a base structure of a radical sensor is obtained and, at block 810B, a filter including a coating is formed on the base structure. In some embodiments, the radical sensor includes a piezoelectric resonator and the base structure includes a piezoelectric material. The filter can selectively react with a radical species and a resonant frequency of the radical sensor can change in response to reaction of the radical species to the filter. In some embodiments, the coating includes an amorphous material (e.g., SiOₓ).

In some embodiments, forming the filter includes at least one of: doping an initial coating to form the coating, forming the coating to have a thickness that ranges from about 5 micrometers to about 50 micrometers, or forming the coating using a deposition process performed at a temperature ranging from about 150° C. to about 450° C. The coating can be formed using any suitable deposition process (e.g., PVD, ALD or CVD). In some embodiments, a deposition process is a thin-film deposition process. For example, the deposition process can be electron beam evaporation (e.g., ion-assisted electron beam evaporation).

In some embodiments, the base structure further includes a front electrode and a back electrode formed on the piezoelectric material. In some embodiments, forming the filter includes forming the filter on the front electrode.

In some embodiments, doping the initial coating includes doping the initial coating with at least one dopant. Any suitable doping process can be used to dope the initial coating. Examples of doping processes include particle bombardment (e.g., He bombardment), particle implantation (e.g., ion implantation), etc. Examples of dopants that can be used to dope the initial coating include Y, P, B, etc.

Forming the coating can include placing a mask (e.g., hard mask or soft mask) over the base structure. The coating can then be formed over the exposed region of the base structure, and the mask may be removed. Alternatively, the coating may be formed on an entirety of a surface, and a portion of the coating may then be selectively removed (e.g., by forming a hard or soft mask over the portion of coating that is not to be removed, and then etching the exposed portion of the coating, and finally removing the mask). Further details regarding blocks 805B and 810B are described above with reference to FIGS. 2A-7.

FIG. 9 is a flow chart of a method 900 for utilizing an acoustic resonance sensor device for radical species detection, in accordance with some embodiments.

At block 905, a manufacturing system flows a plasma using first plasma source settings. The plasma may be generated by a remote plasma source (e.g., a plasma source external to a processing chamber) or by a local plasma source (e.g., a plasma source internal to a process chamber).

At block 910, a radical sensor (e.g., as described hereinabove) is used to measure a concentration or an amount of radical species of a target gaseous species in the plasma. The radical species of a target gaseous species may react with a filter on the radical sensor, causing a mass on a sensing surface of the radical sensor to change. The density and/or mass of the filter may be known, and a change in the mass of the filter may be detected based on a change in the resonant frequency of a piezoelectric material of the radical sensor. This change in mass together with knowledge about the mass of the materials that make up the filter may be used to determine a number of radical species that reacted with the filter, and thus the concentration and/or amount of radical species.

At block 915, processing logic determines whether the measured concentration/amount of radical species exceeds a threshold. For example, processing logic can determine whether the measured concentration/amount of radical species varies from a target concentration/amount of the radical species by more than a threshold amount (e.g., if a difference between the target concentration and the detected concentration is more than a difference threshold). If the difference exceeds a difference threshold, the method continues to block 920 and one or more settings of the plasma source are adjusted. For example, the plasma power may be increased in increase an amount of radical species that are included in the plasma or may be decreased to reduce an amount of radical species that are included in the plasma. If the difference is less than the difference threshold, then the method may end.

Unless specifically stated otherwise, terms such as “first,” “second,” “third,” “fourth,” etc. as used herein are meant as labels to distinguish among different elements and may not have an ordinal meaning according to their numerical designation.

Examples described herein also relate to an apparatus for performing the methods described herein. This apparatus may be specially constructed for performing the methods described herein, or it may include a general purpose system selectively configured to perform methods described herein.

The terms “over,” “under,” “between,” “formed on,” “support,” and “on” as used herein refer to a relative position of one material layer or component with respect to other layers or components. For example, one layer formed on, over, or under another layer may be directly in contact with the other layer or may have one or more intervening layers. Moreover, one layer disposed between two layers may be directly in contact with the two layers or may have one or more intervening layers. Similarly, unless explicitly stated otherwise, one feature disposed between two features may be in direct contact with the adjacent features or may have one or more intervening layers.

The above description is intended to be illustrative, and not restrictive. Although the present disclosure has been described with references to specific illustrative examples and implementations, it will be recognized that the present disclosure is not limited to the examples and implementations described. The scope of the disclosure should be determined with reference to the following claims, along with the full scope of equivalents to which the claims are entitled.

1. A device comprising:
a radical sensor comprising a piezoelectric resonator, the radical sensor comprising:
a base structure comprising a piezoelectric material; and
a filter formed on the base structure to selectively react with a radical species,
wherein a resonant frequency of the radical sensor changes in response to reaction of the radical species to the filter, and wherein the filter comprises at least one of: a crystalline material, a doped coating, or a coating having a thickness that ranges from about 5 micrometers to about 50 micrometers.

2. The device of claim 1, wherein the piezoelectric material comprises a quartz crystal.

3. The device of claim 1, wherein the piezoelectric resonator is a quartz crystal microbalance (QCM) resonator.

4. The device of claim 1, wherein the crystalline material is a polycrystalline material.

5. The device of claim 1, wherein the crystalline material comprises a grain having a grain size that ranges from about 100 nanometers to about 50 micrometers.

6. The device of claim 1, wherein the filter is formed directly on the piezoelectric material.

7. The device of claim 1, wherein the base structure further comprises a front electrode formed on the piezoelectric material, and wherein the filter is formed on the front electrode.

8. The device of claim 1, wherein the doped coating comprises at least one of SiO₂ or SiC doped with at least one of yttrium, phosphorous, or boron.

9. The device of claim 1, wherein the base structure further comprises a mesh formed on a first side of the piezoelectric material, and an electrode formed on a second side of the piezoelectric material opposite the first side, and wherein the filter is formed on the first side of the piezoelectric material.

10. A method comprising:
obtaining a base structure of a radical sensor comprising a piezoelectric resonator, the base structure comprising a piezoelectric material; and
forming, on the base structure, a filter comprising a crystalline material to selectively react with a radical species, wherein a resonant frequency of the radical sensor changes in response to reaction of the radical species to the filter.

11. The method of claim 10, wherein the piezoelectric material comprises a quartz crystal, and wherein the piezoelectric resonator is a quartz crystal microbalance (QCM) resonator.

12. The method of claim 10, wherein forming the filter further comprises depositing the crystalline material directly on the piezoelectric material.

13. The method of claim 12, wherein forming the filter further comprises etching the piezoelectric material using a mesh formed on the piezoelectric material.

14. The method of claim 10, wherein the base structure further comprises a front electrode formed on the piezoelectric material.

15. The method of claim 14, wherein forming the filter further comprises attaching or bonding the crystalline material to a surface of the front electrode.

16. The method of claim 10, wherein the crystalline material comprises a grain having a grain size that ranges from about 100 nanometers to about 50 micrometers.

17. A method comprising:
obtaining a base structure of a radical sensor comprising a piezoelectric resonator, the base structure comprising a piezoelectric material; and
forming, on the base structure, a filter comprising a coating to selectively react with a radical species, wherein a resonant frequency of the radical sensor changes in response to reaction of the radical species to the filter, and wherein forming the filter comprises at least one of: doping an initial coating with a dopant to form the coating, using a base material and the dopant to deposit the coating, forming the coating to have a thickness that ranges from about 5 micrometers to about 50 micrometers, or forming the coating using a deposition process performed at a temperature ranging from about 150° C. to about 450° C.

18. The method of claim 17, wherein the piezoelectric material comprises a quartz crystal, and wherein the piezoelectric resonator is a quartz crystal microbalance (QCM) resonator.

19. The method of claim 17, wherein the base structure further comprises a front electrode, and wherein the filter is formed on the front electrode.

20. The method of claim 17, wherein the dopant comprises at least one of: yttrium, phosphorous, or boron.
